(19) United States
(12) Patent Application Publication
(10) Pub. No.: US 2014/0294202 A1
(43) Pub. Date: Oct. 2, 2014

(54) METHOD AND DEVICE FOR COMMUNICATIONS AND FOR BROADCASTING SOUNDS

(71) Applicant: AWOX, Montpellier (FR)

(72) Inventors: Alain Molinie, Montpellier (FR); Eric Lavigne, Montpellier (FR); Vincent Leclaire, Montpellier (FR)

(73) Assignee: AWOX, Montpellier (FR)

(21) Appl. No.: 14/239,705

(22) PCT Filed: Aug. 20, 2012
(86) PCT No.: PCT/FR2012/051908

§ 371 Date: Mar. 27, 2014

(30) Foreign Application Priority Data
Aug. 19, 2011 (FR) 1157425
Sep. 7, 2011 (FR) 1157957

(51) Int. Cl. H04H 20/86; H05B 37/02; H03G 3/20

(52) U.S. Cl. CPC H04H 20/86; H03G 3/20; H05B 37/0245
USPC 381/107

(57) ABSTRACT

Device for emitting acoustic signals, includes: an upstream bulb cap; a light source including at least one light-emitting diode, powered by the bulb cap; and an electroacoustic transducer, powered by the bulb cap. A reception unit for receiving radio signals representative of a sound signal emitted by the electroacoustic transducer, receives radio signals emitted by at least one first system utilizing at least the Bluetooth specification. An amplifier amplifies the electrical signal supplied by the reception unit so as to transmit an amplified signal to the electroacoustic transducer. A controller controls the amplifier's gain according to signals received by the signal reception unit. The signal reception unit receives signals representative of a command controlling the light power emitted by the light source and controls the light source according to the control signals. The light source and the amplifier are controlled independently and powered by the upstream bulb cap.

### TECHNICAL FIELD OF INVENTION

The present invention concerns a method and a device for communications and for broadcasting sounds. It applies, in particular, to broadcasting data, especially audio or audio-visual media into different zones of a public or private space.

### BACKGROUND OF THE INVENTION

With the development of home networks and the multimedia applications they support, the traditional layout, wherein the network's main player was a PC (“Personal Computer”), is evolving towards a fragmentation of terminals, whether implementing content producer or content consumer functions. One of the drawbacks of this trend is the increased number of “boxes” and accessories in the home, which are not always aesthetically pleasing, not always easy to position, and need a nearby electrical outlet with a power supply unit and audio connection cables in some cases, etc.

The device of document US 2009/207607 is known, comprising a base, a sound emitter and a means of receiving radio signals for controlling sound emission by the sound emitter. In its paragraph [0025], this document envisages that radio signals can be received by means of a sound repeater. However this device, for its part, does not make it possible to extend a wireless network's range. Documents US 2006/039570 and US 2007/110266 describe devices having the same drawbacks.

The present invention aims to remedy all or part of these drawbacks.

### OBJECT AND SUMMARY OF THE INVENTION

To this end, according to a first aspect the present invention envisages a communications device that comprises:
a light source base, referred to as “upstream”,
a light source powered by said base,
a means of receiving radio signals, powered by said base, configured to receive radio signals emitted by at least one first computer system, and
a means of emitting radio signals, powered by said base, configured to retransmit radio signals received by the reception means towards at least one second computer system so as to extend the radio communications range between the first computer system and the second computer system.

Thanks to the present invention, a discrete repeater coupled to a light point is utilized. One of its advantages is that light points are numerous, accessible and electrically powered. Thanks to the utilization of the present invention, the existing sockets of a home or work-place lighting network can be used to create an extended network equipped with several distributed, powered repeaters with no additional wiring compared to the initial lighting network.

According to the present invention, “computer system” means any system equipped with a memory storing at least one program and a central processing unit capable of executing at least one said program, for example a computer server, a computer terminal or a peripheral.

In embodiments, the signal reception means is designed to receive signals representative of a command controlling the light power emitted by the light source, the device comprising a means for controlling the light power emitted by the light source in accordance with said signals.

Thanks to these provisions, a separate remote control for controlling the lighting is realized. Thus, there is no need to turn on the light source in order to broadcast a sound signal since the two subsystems are controlled independently and powered continuously.

In embodiments, the device that is the subject of the present invention comprises a means of declaring the device as a data receiver on a computer network or of discovering it as such, and a means of selecting, from the signals received by the reception means:
data intended only for said device, which are not retransmitted by the emission means, and
data not intended only for said device, which are retransmitted by the emission means.

In embodiments, the means of receiving radio signals and the means of emitting radio signals utilize the DLNA standard and UPnP protocol in order for the device, which forms a renderer as defined by the DLNA standard, to be discovered, as defined by this standard.

It is thus possible from a computer or a mobile phone connected to the network, equipped with a controller utilizing the DLNA standard and UPnP protocol, to discover, as defined by the DLNA standard, each of the accessible devices that are the subjects of the present invention and to control them individually or, using a grouping system, to control them by zones, ensuring synchronization over each of the zones.

In embodiments, the means of receiving radio signals and the means of emitting radio signals utilize the Wi-Fi standard. Thanks to these provisions, a large number of terminals and peripherals can communicate with a high data throughput rate.

In embodiments, the means of receiving radio signals and the means of emitting radio signals utilize the Bluetooth standard. Thanks to these provisions, a large number of terminals and peripherals can communicate.

In embodiments, the means of receiving radio signals is designed to receive signals representative of a sound signal to be emitted by an electroacoustic transducer and the means of emitting radio signals is designed to retransmit signals representative of said sound signal.

In embodiments, the light source comprises a receiver of signals transmitted by power line over the upstream base.

Thanks to each of these provisions, a separate remote control for the lighting is realized. Thus, there is no need to turn on the light source in order to broadcast a sound signal since the two subsystems are controlled independently and powered continuously.

In embodiments, the signal emission means is designed to supply a UPnP profile for the control of the light power emitted by the light source.

In embodiments, the device comprises a socket and a downstream base between the upstream base and the light source.

Thanks to these provisions, the light source can be changed like a traditional light bulb, without modifying or replacing the components performing the functions of receiving or emitting radio signals, audio broadcasting and/or controlling the light source.

In embodiments, the device that is the subject of the invention comprises a means of detecting a user's movement and a means of transmitting, remotely, a signal representative of the detection of movement.

In this way, it is possible to trigger switching on the repetition of radio signals and/or the light according to the presence of a user, or to create an alarm system, possibly with the addition of a camera and/or a microphone.

In embodiments, the device that is the subject of the invention comprises, in addition:
an electroacoustic transducer,
a means of receiving signals representative of a sound signal to be played by the electroacoustic transducer, powered by the upstream base, and
an amplifier powered by the upstream base and designed to amplify the electrical signal supplied by the reception means so as to transmit an amplified signal to the electroacoustic transducer.

Thanks to the present invention, a discrete audio terminal coupled to a light point is utilized. In this way, the existing sockets of a home's lighting network can be used to create a network of distributed, powered electroacoustic transducers with no additional wiring.

In embodiments, the signal reception means is designed to receive signals representative of the sound signal to be emitted by the electroacoustic transducer by utilizing a multipoint network.

In embodiments, the signal reception means is designed to receive by power line signals representative of the sound signal to be emitted by the electroacoustic transducer, said power line powering said light source.

In embodiments, the device that is the subject of the invention comprises a means of controlling the amplifier designed to control the amplifier's gain.

Thanks to these provisions, it is possible to control, remotely, the sound power emitted by each of the devices that are the subject of the invention and, possibly, to slave it to a sensor, for example of a user's position.

In embodiments, the device that is the subject of the invention comprises a sound channel selector designed to select, from several sound signals, the one that is amplified by the amplifier and played by the electroacoustic transducer.

Thanks to these provisions, the different sound channels are distributed over different devices, such as the right and left stereo sound over two suitably located loudspeakers, or two sound media broadcast in two different rooms.

In embodiments, the signal reception means is designed to modulate the light emitted by the light source according to the sound signal to be broadcast.

In this way, the light and music can be coordinated to produce combined effects.

In embodiments, the device that is the subject of the invention comprises a means of detecting a user's movement, the signal reception means being designed to control the amplifier according to the detection of a movement.

In this way, the loudspeaker and/or light can be switched on according to the presence of a user.

The present invention envisages, according to a second aspect, a communications method utilizing a communications device that comprises a light source base, referred to as “upstream”, a light source powered by said base, which method comprises:
a step of receiving radio signals by a reception means powered by said base, wherein radio signals emitted by at least one first computer system are received, and
a step of emitting radio signals by an emission means, powered by said base, wherein radio signals received during the reception step are retransmitted towards at least one second computer system so as to extend the radio communications range between the first computer system and the second computer system.

As the particular features, advantages and aims of this method are similar to those of the device that is the subject of the present invention, they are not repeated here.

According to a third aspect, the present invention envisages a method for playing sounds with a device that comprises:
a light source base, referred to as “upstream”,
a light source powered by said base,
an electroacoustic transducer,
a means of receiving signals representative of a sound signal to be played by the electroacoustic transducer, powered by said base, and
an amplifier powered by said base and designed to amplify the electrical signal supplied by the reception means so as to transmit an amplified signal to the electroacoustic transducer;

this method comprising:
a step of utilizing the DLNA standard and the UPnP protocol, by the signal reception means;
a step of configuring the device as a renderer, as defined by the DLNA standard;
a step of discovering said device, as defined by the DLNA standard, on a network of equivalent devices; and
a step of supplying a UPnP profile by the signal reception means, said profile permitting:
   the light power emitted by the light source to be controlled by a control point, as defined by the DLNA standard; and
   the playing of sounds by the electroacoustic transducer to be controlled by a control point, as defined by the DLNA standard.

As the particular features, advantages and aims of this method are similar to those of the device that is the subject of the present invention, they are not repeated here.

The present invention also concerns a method and a device for synchronizing sound sources. It applies, in particular, to the synchronization of sound broadcasters located remotely.

People have more and more digital audio media and it is now common to share this content over their domestic network by means of the DLNA standard. However, in a domestic environment, more and more sound sources can be used to broadcast a digital audio media item residing on a storage device. For example, from a mobile telephone one may wish to trigger the playing of a shared media item by a computer over several loudspeakers distributed through different rooms in a home.

When a device triggers the playing of a single media item on two sound sources, the latter emitting the same sound or different channels representative of the same media item with a time offset; the quality perceived by the users is then lower.

There are products allowing several sound sources to be synchronized, but these products require either the use of proprietary (non-DLNA) network protocols, or the complete renewal of the DLNA ecosystem, e.g. purchasing new specialist DLNA software for sharing content on one's computer, or purchasing a specialist sharing device.

The present invention aims to remedy all or part of these drawbacks and, in particular, offer the synchronization of several emitting sound sources from a device sharing its content according to the DLNA standard.

To this end, according to a fourth aspect, the present invention envisages a device for synchronizing sound sources, for the playing of an audio content coming from at least one content storage system utilizing the DLNA standard, to form a DLNA server; the device comprising:
a master sound broadcasting system utilizing the DLNA standard to form a DLNA audio renderer,
at least one slave sound broadcasting system utilizing the DLNA standard to form a DLNA audio renderer,
a control system utilizing the DLNA standard to form a DLNA controller designed to:
   discover the audio content available on each DLNA server,
   configure the DLNA audio renderers, and
   trigger the sending of content from a DLNA server to the DLNA audio renderers, using a data transfer protocol and a compressed data format.

In this device:
the master system comprises:
a data transfer protocol decoder,
an audio encoder, which encodes the decoded content found in a compressed audio format to an audio format with no compression and no header information,
a module for transmitting the encoded content using a protocol allowing timing control of slave systems, and
the slave systems are designed to decode and broadcast the audio content received from the master system.

Thanks to these provisions, the time offsets between the signals broadcast by the DLNA renderers are synchronized to below the threshold of human perception. In particular, through the use of a RAW format for the audio data to be broadcast and the RTP timing control protocol, no variable delay can arise in the signal's decompression, or in the transmission over the network by the master system or by the slave systems. In addition, the device that is the subject of the present invention is an open system.

In embodiments, the data transfer protocol is the HTTP protocol.

In embodiments, the audio format with no compression and no header information is the RAW or PCM protocol.

In embodiments, the master system forms a gateway that acts as a server for the various renderers.

In embodiments, the transmission module is designed to carry out encoding using the RTP real time protocol.

In embodiments, the transmission module is designed to carry out encoding using the TCP transmission control protocol.

In embodiments, the master system is designed to broadcast the audio content simultaneously to the slave systems.

According to a fifth aspect, the present invention envisages a method for synchronizing sound sources, which comprises:
a control step utilizing the DLNA standard to:
   discover the audio content available on at least one DLNA server,
   configure DLNA audio renderers, one of which acts as master and each other one acts as a slave, and
   trigger the sending of content from a DLNA server to the DLNA audio renderers, using a data transfer protocol and a compressed data format,
a step of decoding the data transfer protocol by the master audio renderer,
a step of audio encoding, for the encoding by the master audio renderer of the decoded content found in a compressed audio format to an audio format with no compression and no header information,
a step of transmitting the encoded content using a protocol allowing timing control of slave systems, by the master audio renderer, and
a step of decoding and broadcasting the audio content received from the master system.

As the particular features, advantages and aims of this method are similar to those of the device that is the subject of the fourth aspect of the invention, they are not repeated here.

The characteristics of each of the aspects of the invention are intended to be combined to form a device having firstly a sound broadcasting function, secondly a function of repeating signals towards other systems, and thirdly a function of synchronizing audio sources. The principal or particular features of each of the aspects of the present invention therefore constitute particular features of the other embodiments.

### BRIEF DESCRIPTION OF THE DRAWINGS

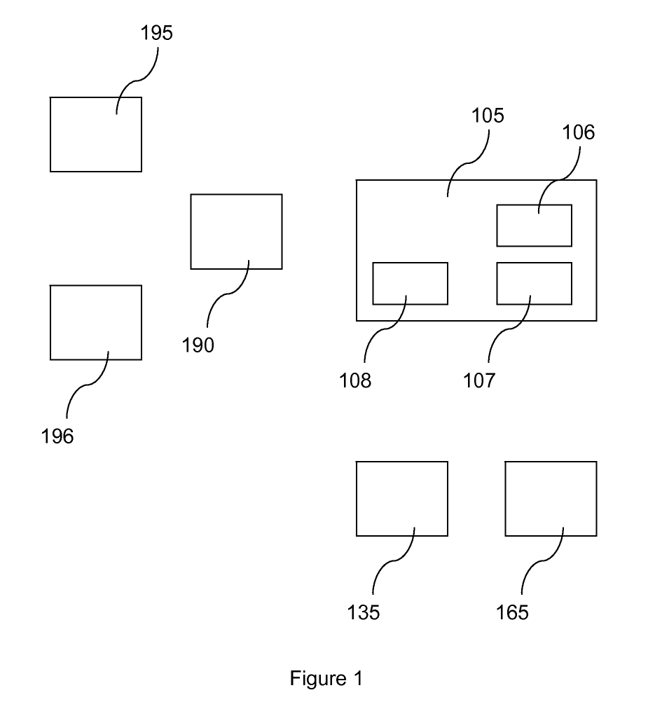

Other advantages, aims and particular features of the present invention will become apparent from the description that will follow, made, as a non-limiting example, with reference to the drawings included in an appendix, in which FIG. 1 represents, schematically, a particular embodiment of the device that is the subject of the invention.

### DETAILED DESCRIPTION OF EMBODIMENTS

FIG. 1 shows a master system 105 and slave systems 135 and 165, audio content servers 195 and 196 and a controller 190. Servers 195 and 196 are to be understood in the sense defined by the DLNA (acronym for Digital Living Network Alliance) standard.

The DLNA association brings together companies manufacturing electronic devices, computer peripherals, personal computers, mobile telephones and service and content operators. DLNA defines an interoperability standard allowing the playing, sharing and control of multimedia devices regardless of their brand or nature. The standard identifies “actors”, some of which can be on the same equipment in the network:
the “server”, which holds the digital content and supplies same, on request,
the “renderer”, which decodes the digital content so that it can be played,
the “player”, which plays the decoded content, and
the “controller”, which makes it possible to browse through the content proposed by the servers and have it played by the renderers and players.

It is noted that the player, renderer and controller can be in a single device, which can be likened to the client in the client/server model: each compatible client (television, hi-fi system, photo frame, mobile telephone, decoder unit, etc.) can retrieve items (video, music, photos) on a DLNA server. This server can be installed on a computer or mobile telephone, or be a standalone unit with a hard disk. The network links can be via Ethernet or Wi-Fi.

DLNA is based on a number of standards, including Wi-Fi, Ethernet and MoCA for the physical layer, UPnP Device Architecture for discovery and control, UPnP AV for media management, HTTP for the transport layer, a wide range of audio, video and image format standards, and DTCP-IP for media protection during transport.

The controller 190 thus:
discovers the content,
at the user's command, configures the broadcast and the number of audio renderers, here systems 105, 135 and 165, and
triggers the sending of content from the servers 195 and 196 to the audio renderers 105, 135 and 165.

The audio renderers transmit, for example, the audio content according to the HTTP protocol (HyperText Transfer Protocol).

The master system 105 comprises an HTTP decoder 106 and an audio encoder 107, which encodes the content in a compressed audio format, e.g. MP3 or WMA, or in a RAW format (Real Audio Format), also known as PCM. It is noted here that RAW is a raw audio format, with no compression. Comparable in size to WAV or AIFF files, the RAW file contains no header information (metadata). The RAW file can be PCM, IEEE 754 or ASCII. The most common extensions are “.raw” or “.pcm”. The RAW file may have no extension.

The sound encoded by the encoder 107 is transported according to the RTP protocol (Real Time Protocol)/TCP protocol (Transmission Control Protocol) by means of a transmission module 108. This RTP/TCP protocol allows timing control of slave systems 135 and 165.

The slave systems 135 and 165 decode, with decoding modules 136 and 166 respectively, and play the audio content they receive.

Thanks to these provisions, the time offsets between the signals broadcast by the renderers are synchronized to within under 10 ms. In particular, through the use of a RAW format for audio data to be broadcast and the RTP timing control protocol, no variable delay can arise in the sound broadcasting by the master system 105 or by the slave systems 135 and 165.

It is noted that, in addition, the device that is the subject of the present invention is an open system.

It is also noted that the master system 105 forms a gateway that acts as a server for the various renderers.

As is understood, a method that is the subject of the invention is a method for synchronizing sound sources, which comprises:
a control step utilizing the DLNA standard to:
   discover the audio content available on at least one DLNA server,
   configure DLNA audio renderers as access points, one of which acts as master and each other one acts as a slave, and
   trigger the sending of content from a DLNA server to the DLNA audio renderers, using a data transfer protocol and a compressed data format,
a step of decoding the data transfer protocol by the master audio renderer,
a step of audio encoding, for the encoding by the master audio renderer of the decoded content found in a compressed audio format to an audio format with no compression and no header information,
a step of transmitting the encoded content using a real-time protocol and a transmission control protocol allowing timing control of slave systems, by the master audio renderer, and

a step of decoding and broadcasting the audio content received from the master system, simultaneously by the master and slave audio renderers.

In one of the particular embodiments (not shown), the device that is the subject of the invention comprises, in at least one renderer:
a light source base, referred to as “upstream”,

a light source powered by said base,
a socket and a downstream base between the upstream base and the light source,
a means of detecting a user's movement,
a means of receiving radio signals, powered by said base, designed to receive radio signals emitted by at least one first computer system, and
a means of emitting sound signals powered by said base and designed to:
retransmit radio signals received by the reception means towards a second computer system so as to extend the radio communications range between the first computer system and the second computer system, and
transmit, remotely, a signal representative of the detection of movement.

According to the present invention, “computer system” means any system equipped with a memory storing at least one program and a central processing unit capable of executing at least one said program, for example a computer server, a computer terminal or a peripheral.

The light source base, referred to as “upstream”, is of known type, e.g. screw or bayonet. The light source powered by said base is of known type, e.g. light-emitting diodes or filament.

The device that is the subject of the invention is declared as an access point in the network thus formed.

According to variants, each means of receiving radio signals and means of emitting radio signals utilizes the Wi-Fi standard, Bluetooth standard, DLNA standard and/or UPnP protocol in order for the device, which forms a renderer as defined by the DLNA standard, to be discovered, as defined by this standard. In the case where the UPnP protocol is utilized, the signal emission means is designed to supply a UPnP profile for the control of the light power emitted by the light source.

The repeaters being well known to the person skilled in the art, they are not detailed here. For entering the repeater's operating parameters, e.g. its identifier (“SSID”) or a code, preferably an application on a mobile phone, e.g. of Smartphone type, or a browser operating on a computer terminal is utilized.

Preferably, the means of receiving radio signals is designed to receive signals representative of a sound signal to be emitted by the electroacoustic transducer, powered by the upstream base, and the means of emitting radio signals is designed to retransmit signals representative of said sound signal.

Preferably, the signal reception means is designed to receive signals representative of a command controlling the light power emitted by the light source, and/or the light source comprises a receiver of signals transmitted by power line over the upstream base.

The device that is the subject of the invention thus forms both a discrete repeater and renderers coupled to a light point, already accessible and powered. In this way, the existing sockets of a home or work-place lighting network can be used to create an extended network equipped with at least one distributed, powered repeater with no additional wiring compared to the lighting network. A large number of terminals and peripherals can communicate with a high data throughput rate.

It is also possible from a computer or a mobile phone connected to the network, equipped with a controller utilizing the DLNA standard and UPnP protocol, to discover, as defined by the DLNA standard, each of the accessible devices that are the subjects of the present invention and to control them individually or, using a grouping system, to control them by zones, ensuring synchronization over each of the zones.

In addition, a separate remote control for controlling the lighting is realized. Thus, there is no need to turn on the light source in order to broadcast a sound signal since the two subsystems are controlled independently and powered continuously. The light source can be changed like a traditional light bulb.

It is noted that some signals can be received by wireless transmission and others by wired reception.

It is possible to trigger switching on the repetition of radio signals and/or the light according to the presence of a user, or to create an alarm system, possibly with the addition of a camera and/or a microphone. Thus, in variants, a camera and/or a microphone are added to the device. The images and/or sounds captured from the detection of movement are then stored in the device or in the home automation system or transmitted remotely. Preferably, a DLNA server is then utilized for streaming (transmission in step with capture) the captured sound signal or captured images. In particular embodiments (not shown), at least one renderer also comprises:
an electroacoustic transducer,
a means of receiving signals representative of a sound signal to be played by the electroacoustic transducer, powered by said base, and
an amplifier powered by said base and designed to amplify the electrical signal supplied by the reception means so as to transmit an amplified signal to the electroacoustic transducer.

The electroacoustic transducer is of known type, e.g. a loudspeaker. It is also noted that several miniaturized electroacoustic transducers can surround the axis of the upstream base to obtain space savings.

The means of receiving signals representative of a sound signal to be played by the electroacoustic transducer takes different forms, according to the variants. Preferably, the signal reception means utilizes the DLNA standard and UPnP protocol in order for the device, which forms a renderer as defined by the DLNA standard, to be discovered, as defined by this standard. The signal reception means is designed to receive signals representative of the sound signal to be emitted by the electroacoustic transducer by utilizing a multipoint network.

In variants, the signal reception means is designed to receive radio signals representative of the sound signal to be emitted by the electroacoustic transducer. For example, this reception of radio signals utilizes the Wi-Fi protocol or the Bluetooth specification.

In variants, the signal reception means is designed to receive by power line signals representative of the sound signal to be emitted by the electroacoustic transducer, said power line powering said light source.

The amplifier that amplifies the electrical signal supplied by the reception means so as to transmit an amplified signal to the electroacoustic transducer is of known type.

As is understood in the light of the preceding description, a discrete audio terminal coupled to a light point is utilized. One of the advantages arising from this is that, with the lighting points being numerous, accessible and powered, many sources can be positioned in a home, office, factory or store without changing the pre-existing electrical network. In this way, the existing sockets of a home's lighting network can be used to create a network of distributed, powered loudspeakers with no additional wiring. It is thus possible from a computer or a mobile phone connected to the network, equipped with a controller utilizing the DLNA standard and UPnP protocol, to discover, as defined by the DLNA standard, each of the accessible devices that are the subjects of the present invention and to control them individually or, using a grouping system, to control them by zones, ensuring synchronization over each of the zones.

The IP (“Internet Protocol”) addresses are managed in order to manage the profile, the light emission and the sound emission, in the case of the device combining these functions.

The device thus reacts according to signals supplied by other devices so as to constitute an intelligent network. For example, for playing sounds, according to the other devices' assignments to other channels, a device selects the channel (for example, right or left, in stereo or by zone in the case where several media items are broadcast in parallel in different zones) that it broadcasts. Each device sends messages over the network to indicate its role determined in this way. The device network thus converges, by successive adaptations, to an optimum configuration. Similarly, for managing the colors of lights emitted by the devices, each device determines its color according to the color broadcast by the other devices. It is noted that different modes of operation can synchronize the colors or, in contrast, differentiate them depending on the visual effects sought. Lastly, the colors and sounds can be made dependent, as in systems called “psychedelic”. The concept of message here also includes the concepts of emitting instructions and the concepts of complying with an instruction received from another device. In another application, in order to reduce electrical consumption, the devices determine whether they should stop emitting light or sound, based on messages transmitted by the other devices and, possibly, by sensors, e.g. presence sensors.

It is noted that a device that is the subject of the invention can thus play the role of control point, renderer or server with regard to other identical devices.

In a third embodiment, in addition to the characteristics of the second embodiment, the device that is the subject of the invention comprises:
a means of controlling the amplifier designed to control the amplifier's gain, such that the sound power emitted by each of the devices that are the subject of the invention is controlled remotely and, possibly, slaved to a sensor, for example of a user's position,
a sound channel selector designed to select, from several sound signals, the one that is amplified by the amplifier and played by the electroacoustic transducer, so as to broadcast one of the various sound channels, for example the right and left stereo sound over each of a plurality of electroacoustic transducers positioned in the same room, or two sound media broadcast in two different rooms, and/or
a means of controlling the light power emitted by the light source controlled by means of the signal reception means. In this way, a separate remote control for controlling the lighting is realized. Thus, there is no need to turn on the light source in order to broadcast a sound signal since the two subsystems are controlled independently.

Preferably, in order to implement this last option, the signal emission means is designed to supply a UPnP profile for the control of the light power emitted by the light source. This UPnP profile represents both the device's ability to broadcast sound signals and its ability to turn on the light source.

Preferably, for each of these embodiments, the device comprises a socket and a downstream base between the upstream base and the light source. Thus, the light source can be changed like a traditional light bulb, without modifying or replacing the components performing the functions of audio broadcasting and/or controlling the light source, which are located between the upstream base and the downstream base.

In variants, the signal reception means is designed to modulate the light emitted according to the sound signal to be played, e.g. according to an average over the last seconds. In this way, the light and music can be coordinated to produce combined effects. It is noted that it is not only the light power that can be modulated according to the sound signal but also the color, for example in the case where several light-emitting diodes emitting in different wavelength ranges are integrated into the light source.

The addition of a separate remote control and/or a “Lighting Control” UPNP profile controlling the lighting allows the upstream base to be left permanently powered. Since the lighting points are generally controlled by a switch, it would otherwise be necessary to switch on this switch in order to benefit from sound broadcasting.

It should be noted that, in itself, the creation of a hybrid profile corresponding to two profiles is an aspect of the present invention. In particular, a double profile of sound renderer and light renderer is a particular feature of this aspect of the present invention.

This third embodiment makes it possible to realize lighting control according to the music played, as a mode of operation for a musical evening, or a dance.

It is also noted that a special mode of operation of this third embodiment of the present invention comprises a simulation of presence in the premises equipped (in particular to reduce the risks of break-ins), by randomly triggering playing music and/or emitting light.

In a fourth embodiment, the device that is the subject of the invention comprises a means of detecting a user's movement, the signal reception means being designed to control the amplifier according to the detection of a movement. In this way, the loudspeaker and/or light can be switched on according to the presence of a user. This fourth embodiment makes it possible for the user to continue listening to the media, e.g. the radio, which is the main benefit, while at the same time saving energy and reducing noise pollution.

Utilizing a coupling with a movement detector thus allows an automatic “follow me” (the sound broadcasting follows the user from one place to another) to be realized.

Preferably, the reception means is designed to transmit, remotely, a signal representative of the detection of movement. An alarm system is thus created, by making it possible to transmit, remotely, the movement detection information or by triggering an alarm when the user has set the home automation system to alarm mode.

In variants, a camera and/or a microphone are added to the device of the fourth embodiment. The images and/or sounds captured from the detection of movement are then stored in the device or in the home automation system or transmitted remotely. Preferably, a DLNA server is then utilized for streaming (transmission in step with capture) the sound signal or image.

Through utilization of the present invention, creating a multi-room audio system requires no wiring for the electroacoustic transducers since the existing sockets of a home's lighting network are used to create a distributed loudspeaker network. The use of DLNA/UPnP for the discovery of each of these electroacoustic transducers gives each device the role of a renderer, as defined by DLNA/UPnP, in the home automation system. It is thus possible from a computer or a mobile phone connected to the network, equipped with a DLNA/UPnP controller, to discover them and to control them individually or, using a grouping system, to control them by zones, retaining audio synchronization over each of the zones.

As described above, advanced implementations also make it possible to:
control the sound level and play the music received by each of the electroacoustic transducers,
distribute the different sound channels over each of the devices,
add a lamp to the loudspeaker and use the UPnP profiles for controlling light devices to define the light intensity of the lamp,
coordinate the light and music to produce combined effects,
add a movement control system to trigger the switching on of the loudspeaker and/or light, and/or
create an alarm system with the addition of a camera and/or a microphone.

It is noted that the present invention also makes it possible to create audio-light ceiling-mounted fixtures, which allows the sound quality to be improved.

It is also noted that the particular features of the different embodiments can be combined in other embodiments to form devices having all or part of the functions described above.

1-21. (canceled)

22. Device for emitting acoustic signals, that comprises:
a bulb cap, referred to as “upstream”,
a light source comprising at least one light-emitting diode, powered by said upstream bulb cap,
an electroacoustic transducer, powered by said upstream bulb cap,
a means of receiving radio signals representative of a sound signal to be emitted by the electroacoustic transducer, powered by the upstream bulb cap, that receives radio signals emitted by at least one first system equipped with a memory storing at least one program and a central processing unit capable of executing at least one said program, this reception of radio signals utilizing at least the Bluetooth specification,
an amplifier powered by the upstream bulb cap amplifying the electrical signal supplied by the reception means so as to transmit an amplified signal to the electroacoustic transducer,
a means of controlling the amplifier designed to control the amplifier's gain according to signals received by the signal reception means;
wherein the signal reception means receives signals representative of a command controlling the light power emitted by the light source and controls the light source according to said control signals,
the light source and the amplifier being controlled independently.

23. A device according to claim 22, that further comprises a sound channel selector that selects, from several sound signals, the one that is amplified by the amplifier and played by the electroacoustic transducer.

24. A device according to claim 22, wherein the signal reception means modulates the light emitted by the light source according to the sound signal to be broadcast.

25. A device according to claim 22, wherein the signal reception means receives signals representative of the sound signal to be emitted by the electroacoustic transducer by utilizing a multipoint network.

26. A device according to claim 22, that further comprises a means of emitting radio signals, powered by said upstream bulb cap, that retransmits radio signals received by the reception means towards a second system equipped with a memory storing at least one program and a central processing unit capable of executing at least one said program, so as to extend the radio communications range between the first system and the second system.

27. A device according to claim 26, wherein the means of receiving radio signals and the means of emitting radio signals utilize at least the DLNA standard and UPnP protocol in order for the device, which forms a renderer as defined by the DLNA standard, to be discovered, as defined by this standard.

28. A device according to claim 26, wherein the means of receiving radio signals and the means of emitting radio signals utilize at least the Wi-Fi standard.

29. A device according to claim 26, wherein the means of receiving radio signals receives signals representative of a sound signal to be emitted by an electroacoustic transducer and the means of emitting radio signals retransmits signals representative of said sound signal.

30. A device according to claim 26, wherein the means of emitting radio signals supplies a UPnP profile for the control of the light power emitted by the light source.

31. A device according to claim 22, wherein the means of receiving radio signals utilizes the Wi-Fi standard.

32. A device according to claim 22, that further comprises
a means of declaring the device as a data receiver on a computer network or of discovering it as a data receiver on a computer network, and
a means of selecting, from the signals received by the reception means:
data intended only for said device, which are not retransmitted by the emission means, and data not intended only for said device, which are retransmitted by the emission means.

33. A device according to claim 22, that further comprises a socket and a downstream bulb cap between the upstream bulb cap and the light source.

34. A device according to claim 22, that further comprises a means of detecting a user's movement and a means of transmitting, remotely, a signal representative of the detection of movement.

35. A device according to claim 22, wherein the signal reception means receives signals representative of the sound signal to be emitted by the electroacoustic transducer by utilizing a multipoint network.

36. A device according to claim 22, that further comprises a sound channel selector that selects, from several sound signals, the sound signal that is amplified by the amplifier and played by the electroacoustic transducer.

37. Method for emitting acoustic signals with a device comprising:
a light source bulb cap, referred to as “upstream”,
a light-emitting diode light source, powered by said upstream bulb cap,
an electroacoustic transducer, powered by said upstream bulb cap, and
an amplifier, powered by said upstream bulb cap, the light source and the amplifier being controlled independently and powered continuously when the upstream bulb cap is powered;
the method comprising:
an amplification step, during which the electrical signal supplied by the reception means is amplified so as to transmit an amplified signal to the electroacoustic transducer,
a step of receiving radio signals representative of a sound signal to be emitted by the electroacoustic transducer, powered by the upstream bulb cap, during which radio signals emitted by at least one first system equipped with a memory storing at least one program and a central processing unit capable of executing at least one said program, are received, this reception of radio signals utilizing at least the Bluetooth specification,
a step of controlling the amplifier's gain according to signals received by the signal reception means, so as to transmit an amplified signal to the electroacoustic transducer, and
a step of receiving signals representative of a command controlling the light power emitted by the light source and of controlling the light source according to said control signals.

38. A method according to claim 37, that further comprises:
a step of emitting radio signals by an emission means, powered by said upstream bulb cap, wherein radio signals received during the reception step are retransmitted towards at least one system equipped with a memory storing at least one program and a central processing unit capable of executing at least one said program, so as to extend the radio communications range between the first system and the second system.

39. A method according to claim 37, that comprises:
a step of utilizing the DLNA standard and the UPnP protocol, by the signal reception means;
a step of configuring the device as a renderer, as defined by the DLNA standard;
a step of discovering said device, as defined by the DLNA standard, on a network of equivalent devices; and
a step of supplying a UPnP profile by the signal reception means, said profile permitting:
the light power emitted by the light source to be controlled by a control point, as defined by the DLNA standard; and
the playing of sounds by the electroacoustic transducer to be controlled by a control point, as defined by the DLNA standard.

40. A method according to claim 37, that comprises:
a control step utilizing the DLNA standard to:
discover the audio content available on at least one DLNA server,
configure DLNA audio renderers, one of which acts as master and each other one acts as a slave, and
trigger the sending of content from a DLNA server to the DLNA audio renderers, using a data transfer protocol and a compressed data format,
a step of decoding the data transfer protocol by the master audio renderer,
a step of audio encoding, for the encoding by the master audio renderer of the decoded content found in a compressed audio format to an audio format with no compression and no header information,
a step of transmitting the encoded content using a protocol allowing timing control of slave systems, by the master audio renderer, and
a step of decoding and broadcasting the audio content received from the master system.
